(19) United States
(12) Patent Application Publication
(10) Pub. No.: US 2017/0338804 A1
(43) Pub. Date: Nov. 23, 2017

(54) Apparatus, System, and Method for an Acoustic Response Monitor

(71) Applicants: Jacob H. Gunther, North Logan, UT (US); VSSL LLC, Hyrricane, UT (US)

(72) Inventors: Jacob H. Gunther, North Logan, UT (US); Dan Allen, Washington, UT (US)

(21) Appl. No.: 15/594,638

(22) Filed: May 14, 2017

Related U.S. Application Data
(60) Provisional application No. 62/336,575, filed on May 14, 2016.

(51) Int. Cl. H03H 21/00; G08B 21/18; G06F 3/16

(52) U.S. Cl. CPC H03H 21/0012; G06F 3/165; G08B 21/182

(57) ABSTRACT

An acoustic response monitor. The acoustic response monitor includes a speaker, a microphone, and a response analyzer in electrical communication with the speaker and the microphone. The speaker is configured to generate a sound in response to an excitation signal. The microphone is configured to generate a microphone signal in response to a sound. The response analyzer is configured to generate an adaptive filter to minimize a difference between the excitation signal as modified by the adaptive filter and the microphone signal. The response analyzer may be configured to determine a difference between the adaptive filter and a previously generated adaptive filter. The response analyzer may be configured to trigger an alarm if the difference exceeds a predetermined threshold.

### CROSS-REFERENCE TO RELATED APPLICATIONS

This application claims the benefit of U.S. Provisional Patent Application No. 62/336,575 entitled “Apparatus, System, and Method for an Acoustic Response Monitor,” which was filed on May 14, 2016, which is hereby incorporated by reference.

### SUMMARY

An embodiment of the invention provides an acoustic response monitor. The acoustic response monitor includes a speaker, a microphone, and a response analyzer in electrical communication with the speaker and the microphone. The speaker is configured to generate a sound in response to an excitation signal. The microphone is configured to generate a microphone signal in response to a sound. The response analyzer is configured to generate an adaptive filter to minimize a difference between the excitation signal as modified by the adaptive filter and the microphone signal. The response analyzer may be configured to determine a difference between the adaptive filter and a previously generated adaptive filter. The response analyzer may be configured to trigger an alarm if the difference exceeds a predetermined threshold. Other embodiments are also described.

### BRIEF DESCRIPTION OF THE SEVERAL VIEWS OF THE DRAWINGS

FIG. 1 depicts one embodiment of a system for an acoustic response monitor.

FIG. 2 is a block diagram depicting one embodiment of the response analyzer of FIG. 1.

FIG. 3 is a block diagram depicting one embodiment of the digital signal processor of FIG. 2.

FIG. 4 depicts one embodiment of a system for an acoustic response monitor including a plurality of microphones.

FIG. 5 depicts one embodiment of a system for an acoustic response monitor including a plurality of monitoring areas.

FIG. 6 is a flowchart depicting one embodiment of a method for an acoustic response monitor.

FIG. 7 is a diagram of one embodiment of a computer system for facilitating the execution of the response analyzer of FIG. 1.

FIGS. 8 and 9 depict one embodiment of a system for a response analyzer.

Throughout the description, similar reference numbers may be used to identify similar elements.

### DETAILED DESCRIPTION

In the following description, specific details of various embodiments are provided. However, some embodiments may be practiced with less than all of these specific details. In other instances, certain methods, procedures, components, structures, and/or functions are described in no more detail than to enable the various embodiments of the invention, for the sake of brevity and clarity.

While many embodiments are described herein, at least some of the described embodiments provide a system for monitoring an acoustic response of a monitored volume.

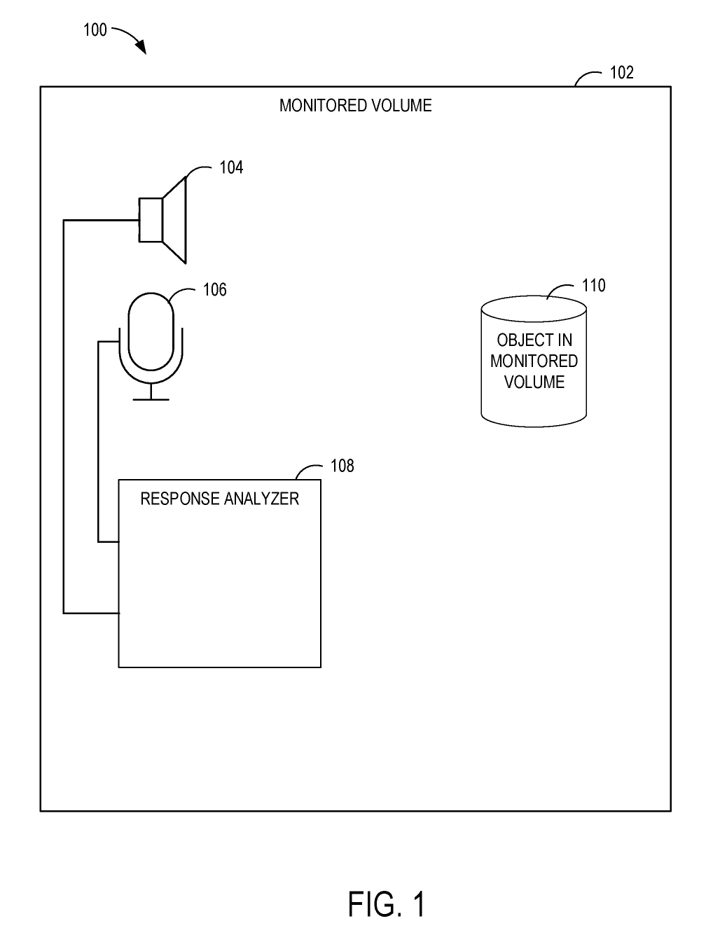

FIG. 1 depicts one embodiment of a system 100 for an acoustic response monitor. The system 100 includes a monitored volume 102, a speaker 104, a microphone 106, and a response analyzer 108. The system 100 calculates an acoustic response baseline for the monitored volume 102 and monitors the monitored volume 102 to determine a change to the acoustic response of the monitored volume 102.

The monitored volume 100, in certain embodiments, is a volume filled with a fluid capable of propagating pressure waves. For example, the volume may be defined by the walls, ceiling, and floor of a room, and the fluid in the volume may be air. Pressure waves in the air in this example may be in the form of sound. The sound may be in a frequency band that is audible to the average person, or may be in a frequency band above or below the range that is audible to the average person.

In another example, the monitored volume 100 is an open space not bounded by non-fluid barriers. In some embodiments, the monitored volume 100 is relatively large, such that it effectively does not have non-fluid barriers. For example, the monitored volume 100 may include a large warehouse space.

In yet another example, the monitored volume 100 is a container holding a fluid that is a liquid. The container may be of any size. In one embodiment, the container is a swimming pool and the liquid is water.

In one embodiment, the speaker 104 is a transducer capable of generating sound from an electrical signal. The speaker 104 may be a loudspeaker, such as a dynamic speaker. In another embodiment, the speaker 104 is a different type of speaker, such as a piezoelectric speaker, a flat panel speaker, or a rotary woofer. The speaker 104 may be any type of speaker known in the art capable of producing a pressure wave in the fluid medium filling the monitored volume 102.

In certain embodiments, the microphone 106 is a transducer that converts pressure waves into electrical signals. The microphone 106 may be a dynamic microphone that uses electromagnetic induction to produce the electrical signal. In another embodiment, the microphone 106 is a condenser microphone that uses capacitance to produce the electrical signal. In yet another embodiment, the microphone 106 is a piezoelectric microphone that uses piezoelectricity to produce the electrical signal. The microphone 106 may be any type of microphone known in the art capable of producing an electric signal in response to pressure waves.

In an alternative embodiment, the speaker 104 is a transducer capable of generating electromagnetic waves and the microphone 106 is a transducer that converts received electromagnetic waves into an electrical signal. In another embodiment, the speaker 104 and the microphone are transducers operating on other types of mechanical waves than pressure waves. For example, the speaker 104 may generate transverse waves and the microphone 106 may receive transverse waves and generate an electrical signal corresponding to the received transverse wave. In many embodiments described herein, terms corresponding to pressure waves, such as “sound” and “audio” are used. In embodiments in which non-pressure waves are employed, similar principles and processes are applied to produce and process the non-pressure waves and corresponding terms appropriate for non-pressure waves may be substituted for terms typically used for pressure waves. Such embodiments should be considered to be within the scope of this disclosure.

The response analyzer 108, in some embodiments, models a response of the monitored volume. For example, let s[n] be a discrete-time (sampled data) version of an excitation or probe signal. The signal s[n] drives a digital-to-analog converter (DAC) whose output is a continuous-time (analog voltage) signal denoted s(t). This signal or a modified (e.g. amplified) version thereof drives a speaker 104. The sound wave emitted by the speaker 104 travels along many paths through the monitored volume 102. The sound wave arrives at the microphone 106. A path along which a sound wave travels has associated with it a time delay and a scale factor. The path time delay is the amount of time required for sound to propagate from the speaker to the microphone along the path through the monitored volume 102. Some paths have short delay and other paths have long delay. At a given instant, the microphone 106 receives sound over a wide range of delays. The scale factor accounts for attenuation due to path loss as well as change in amplitude due to reflections. In general, long delay paths have larger attenuation (and therefore smaller scale factors) than short delay paths.

When two or more distinct paths have the same time delay, the sound waves traveling along these paths combine at the microphone 106 yielding an overall total scale factor that is associated with that particular time delay. Let τ denote time delay and let a(τ) denote scale factor for all paths having delay τ. In general, the microphone 106 collects sound over a continuum of delays. The microphone 106 outputs a voltage signal denoted x(t). For a single sound path with delay τ and scale a(τ), the microphone output may be modeled as

x(t)=a(τ)s(t−τ)

for all time t. When multiple sound paths are present, the total value of the microphone signal is obtained by integrating over all delays,

x(t)=∫₀^{∞}a(τ)s(t−τ)dτ

for all time t. This model assumes that the shortest time delay is 0 seconds, which corresponds to the physical condition that sound cannot arrive at the microphone 106 before it is produced by the speaker 104. The model above places no upper limit on the longest delay (upper limit of integration is infinity), however in some embodiments, some longest delay τₘₐₓ is employed,

x(t)=∫₀^{τ}^{ₘₐₓ}a(τ)s(t−τ)dτ.

For practical purposes, the range of time delays may be discretized provided the resolution of the quantization is sufficiently fine. Because in some embodiments the microphone output signal is sampled by an analog-to-digital converter (ADC) yielding the discrete-time (sampled data) signal x[n], it is convenient to use the ADC sampling interval T_{S} (seconds/sample) in discretizing time delay. To this end, let a[k] be the aggregated scale factor for all paths having delay approximately equal to kT_{S}. Then a discrete-time model for x[n] is

$$x [ n ] = {\sum }_{k = 0}^{{k}_{max}} a [ k ] s [ n - k ]$$

for all sample times n, where kₘₐₓ=τₘₐₓ/T_{S}. The functions a(τ) and a[k] are referred to as the impulse response of the monitored volume 102. The impulse response models sound propagation within the monitored volume 102.

As sound travels along many paths through the monitored volume 102, it interacts with objects 110 it encounters. Sound may be reflected, absorbed, transmitted, refracted, and/or diffracted. Sound touches everything in the monitored volume 102. The distribution in the monitored volume 102 of hard objects including architectural structures such as walls, windows, doors, floor and ceiling, and soft objects such as carpet, furniture, and curtains is modeled by a(τ) in the continuous-time model and by a[k] in the discrete-time model. When an object 110 is introduced into or removed from the monitored volume 102, or if an existing object 110 moves within the monitored volume, this changes the paths for sound propagation and modifies the way that sound is reflected, absorbed, transmitted, refracted, and/or diffracted. These changes are manifested in the impulse response a(τ) and a[k]. Therefore, if the impulse response can be measured, then movement of objects 110 and the appearance and disappearance of objects 110 within the monitored volume 102 can be detected. The opening and closing of access points (doors and windows) can also be detected.

In some embodiments, the response analyzer 108 measures the response a[k], k=0, 1, 2, . . . , kₘₐₓ using an adaptive filter configured for system identification. A computer program controls the measurement process. The response analyzer 108, in one embodiment, generates or receives an excitation signal s[n] containing audio information. The response analyzer 108 provides the excitation signal or a signal generated from the excitation signal to the speaker 104. In some embodiments, the response analyzer 108 receives an electrical signal from the microphone 106. In one embodiment the response analyzer 108 generates or receives an excitation signal s[n] containing audio information. The response analyzer 108 provides the excitation signal or a signal generated from the excitation signal to the speaker 104. In some embodiments, the response analyzer 108 receives signal x[n] from the microphone. The response analyzer may pass the excitation signal s[n] through a filter, such as a finite impulse response filter (FIR), with impulse response b[k], k=0, 1, 2, . . . , kₘₐₓ producing output signal y[n]. Using adaptive filtering algorithms such as least mean square (LMS) or recursive least squares (RLS), the program adjusts the coefficients b[k] until the output y[n] matches the microphone signal x[n]. When the squared error/difference between these two signals is zero on average, made to be as small as possible, or made to be below a predetermined or adaptive threshold, then b[k] can be assumed to be approximately equal to a [k]. The quality of the approximation depends on the size of the mean-square error between y[n] and x[n], background noise, and on the qualities of the excitation s[n]. In general, y[n] will model x[n] over the frequency band of the excitation signal s[n]. In some embodiments, a broadband noise-like signal will be used for s[n] but other signals such as speech or music can also be used.

As will be appreciated by one skilled in the art, many different filter structures could be used including finite impulse response filters and infinite impulse response filters. One skilled in the art will also recognize that many different algorithms may be used to update the parameters of these filters to learn the impulse response of the monitored volume. Implementation of these filters and adaptive algorithms may be performed in the time domain, frequency domain, frequency sub-bands, or some other transform domain. While the filter structures and adaptive algorithms for each of these embodiments may be different from one another for a given system, in each case, the generated adaptive filter or adaptive filters constitute a representation of the response of the monitored volume 102.

In one embodiment, the response analyzer 108 detects changes in the monitored volume 102 by repeatedly probing the monitored volume 102 over time on a predetermined schedule. For example, the response analyzer 108 may compare the adaptive filter response and the baseline response every ten seconds. As will be appreciated by one skilled in the art, any predetermined schedule may be employed by the response analyzer 108. In another embodiment, the response analyzer 108 compares the adaptive filter response and the baseline response based on an adaptive schedule. For example, in response to determining that the difference between the adaptive filter response and the baseline response has changed since one or more previous readings, the response analyzer 108 may reduce the time between comparisons.

In certain embodiments, each probe cycle produces a measurement of the impulse response. For example, let bᵢ[k] denote the impulse response measured on the ith measurement cycle. If objects 110 within the monitored volume 102 as well as the objects 110 that define the boundary of the monitored volume (such as doors and windows) have remained unchanged between consecutive measurement cycles i−1 and i, then it is expected that bᵢ[k]=bᵢ₋₁[k] for k=0, 1, 2, . . . kₘₐₓ. Some errors are an inevitable part of the measurement process. Therefore, change detection can be formulated as

$$decision = \{ \begin{matrix}no change , & if dist ( {b}_{i} , {b}_{i - 1} ) < threshold , \\ change , & otherwise ,\end{matrix} \\ where \\ dist ( {b}_{i} , {b}_{i - 1} ) = \sqrt{{\sum }_{k = 0}^{{k}_{max}} {( {b}_{i} [ k ] - {b}_{i - 1} [ k ] )}^{2}} .$$

In certain embodiments, a baseline response bₒ[k] is established, and the response from the current measurement cycle bᵢ[k] is compared to the baseline, dist(bᵢ, b₀). To reduce false alarm rates, other embodiments may apply statistical tests involving the mean and standard deviation of dist(bᵢ, b₀).

In certain embodiments, a change in the current response bᵢ[k] and the baseline response b₀[k] indicates a change to the physical makeup of the monitored volume 102. For example, placing an object 110 in the monitored volume 102 may change the propagation of sound waves in the monitored volume 102 and thus, the response of the monitored volume. Consequently, the current response bᵢ[k] is different than it would be if the object 110 was not in the monitored volume 102. Since the response of the monitored volume 102 is changed by moving the object, the adaptive filter generated by the response analyzer 108 also changes. The response analyzer 108, compares the current adaptive filter response bᵢ[k] to a previously generated adaptive filter baseline bₒ[k], and if the difference is large enough, triggers an alarm or communicates an alarm condition to an external system indicating that something significant in the monitored volume 102 has changed. Consequently, the response analyzer 108 may infer a change to the physical makeup of the monitored volume 102 in response to the probe signal s[n] caused by the introduction of the object 110 into the monitored volume 102.

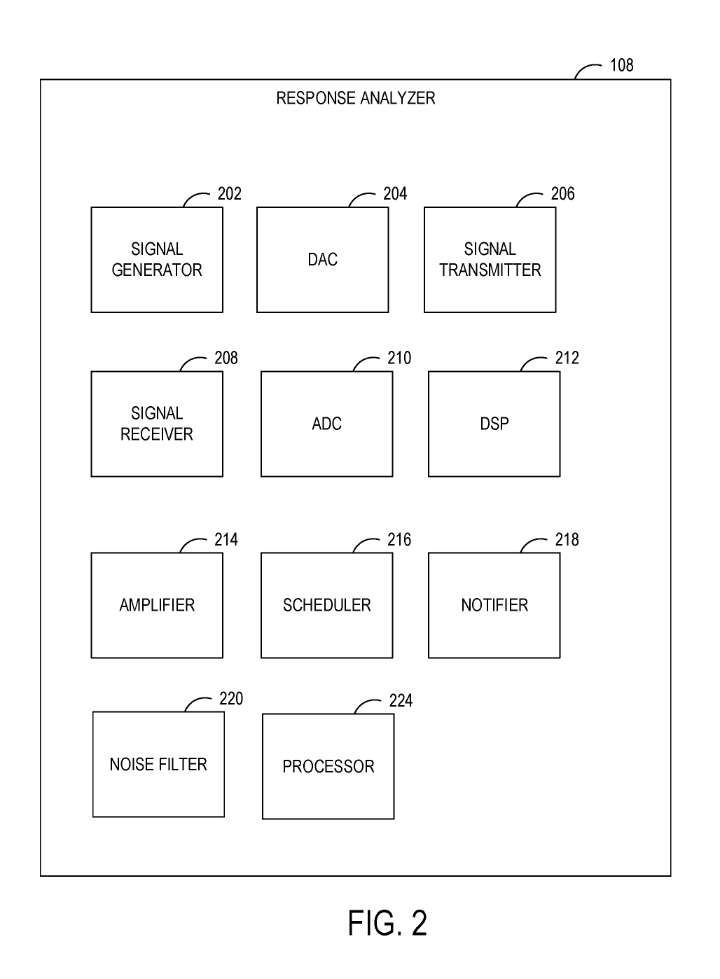

The object 110 may be any type of object that modifies the propagation of sound waves in the monitored volume 102. For example, the object may be a person entering the monitored volume 102. Modifying the location or position of the object 110 within the monitored volume 102 may also result in a change to the response of the monitored volume 102, a change in the adaptive filter response bᵢ[k] generated by the response analyzer 108 relative to a previously generated adaptive filter, and an inference by the response analyzer 108 that the physical makeup of the monitored volume has changed. The response analyzer 108 is described in greater detail in relation to FIG. 2 below.

Since the system 100, in certain embodiments, is capable of determining significant changes to the monitored volume 102, it can be used to monitor the monitored volume 102 for changes and generate alerts in response to significant changes, including the introduction of objects to the monitored volume 102, the removal of objects from the monitored volume 102, and translation of objects within the monitored volume 102. Other changes that impact acoustic response within the monitored volume can also be tracked, such as changes in temperature or noise. The system 100 can therefore be employed as a security device that is triggered by changes such as an opened door or a person entering a room, a presence sensor that determines the presence of a person in a room to manage lighting and thermostat control, a pool monitor to trigger an alarm when an unexpected object, such as a child, enters a pool, or any other change to a fluid-filled volume that significantly changes the acoustic response of that volume.

FIG. 2 is a block diagram depicting one embodiment of the response analyzer 108 of FIG. 1. The response analyzer 108 includes a signal generator 202, a digital-analog converter (“DAC”) 204, a signal transmitter 206, a signal receiver 208, an analog-digital converter (“ADC”) 210, a digital signal processor (“DSP”) 212, an amplifier 214, a scheduler 216, a notifier 218, a noise filter 220, and a processor 224. The response analyzer 108 provides an output signal, receives an input signal, and analyzes changes to the differences between the output signal and the input signal over time.

The signal generator 202, in one embodiment, generates an electronic signal containing information corresponding to a desired output pressure wave. For example, the signal generator 202 may generate an MP3 file containing information to reproduce audio in the range audible by an average person. The electronic signal generated by the signal generator 202 may be any type of electronic signal containing audio information. For example, the output signal may be a digital audio stream or an analog audio signal. In some embodiments, the signal generator 202 receives an external signal containing audio information. In some embodiments, the signal generated by the signal generator 202 is transmitted to the DSP 212 for processing.

The signal generated by the signal generator 202 may include information to produce any type of pressure wave. For example, the signal may correspond to white noise, and the speaker 104 may produce white noise in response to the signal. In another example, the signal may correspond to music, to spoken word, to comfort sounds, to random noise, to tones, to sound above the average range of human hearing, to sound below the range of human hearing, or any other type of pressure wave. In certain embodiments, the signal may result in sound falling in a band between 200 Hz and 4 kHz. In another embodiment, the signal results in sound falling in a band between 5 Hz and 40 Hz. In yet another embodiment, the signal results in sound falling in a band below 200 kHz. The pressure waves produced in response to the signal may be in any frequencies that propagate in the fluid contained in the monitored volume 102.

The signal generated by the signal generator 202 is transmitted to the speaker 104 and the DSP 212 by the signal transmitter 206. This signal received from the signal transmitter 206 by the DSP 212 is the excitation signal. In some embodiments, the signal is processed by the DAC 204 prior to or at the time of transmission to the speaker 104. In certain embodiments, the signal is processed by the amplifier 214 prior to or at the time of transmission to the speaker 104.

The signal receiver 208 receives a signal generated from the microphone 106 (the “microphone signal”). The microphone signal may be any type of signal containing audio information. For example, the microphone signal may be an analog electric signal produced by the microphone 106.

In some embodiments, the microphone signal is processed by the amplifier 214. In one embodiment, the microphone signal is processed by the ADC 210 to convert an analog microphone signal to a digital microphone signal.

The excitation signal and the microphone signal received by the signal receiver 208 are passed to the DSP 212. The microphone signal received by the DSP 212, in some embodiments further processed by the amplifier 214 and/or the ADC 210, is the physical path output. Here and elsewhere in this disclosure, “physical path” refers to the response of the monitored volume. The DSP 212 processes the signals to determine a difference between the excitation signal as modified by an adaptive filter, which is the adaptive filter output, and the physical path output. In some embodiments, the DSP 212 generates the adaptive filter to minimize the difference between the adaptive filter output and the physical path output. The adaptive filter output is a filtered version of the excitation signal. The physical path output is the microphone signal.

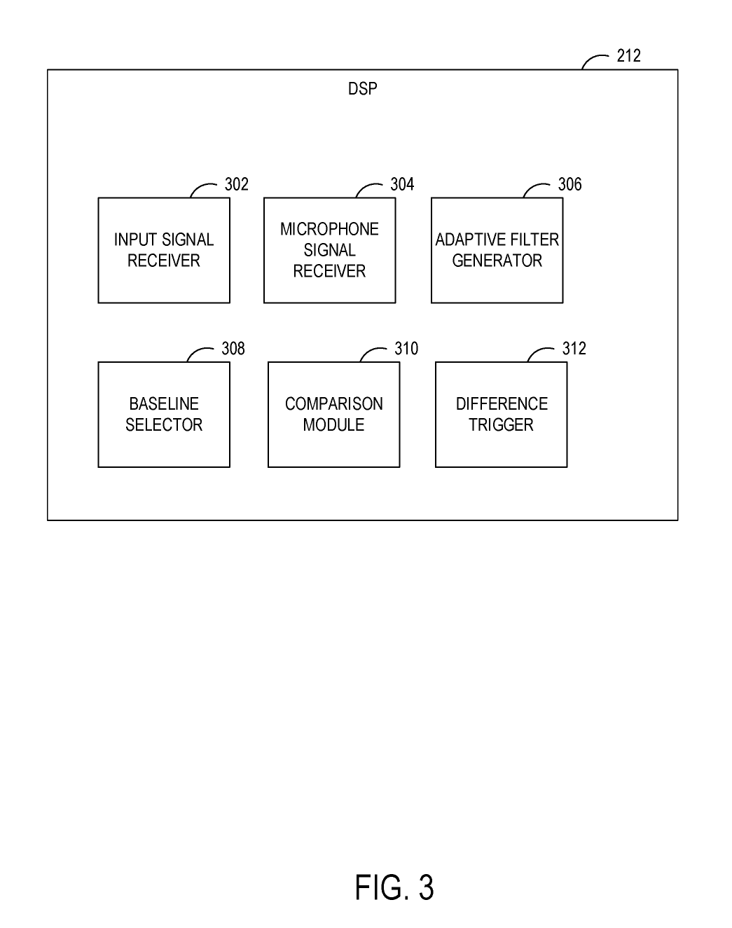

In some embodiments, the DSP 212 is a microprocessor. The microprocessor may be configured to execute instructions to perform the functions of the DSP 212 as described herein. In another embodiment, the DSP 212 is a field programmable gate array (“FPGA”). In another embodiment, the DSP 212 includes one or more complex instruction set computing (CISC) microprocessors, reduced instruction set computing (RISC) microprocessors, very long instruction word (VLIW) microprocessors, processors implementing other instruction sets, or processors implementing a combination of instruction sets. The DSP 212 is described greater detail in relation to FIG. 3 below.

The scheduler 216, in one embodiment, generates a schedule for comparing the adaptive filter response and baseline response. In one embodiment, the scheduler 216 generates a schedule based on predetermined time intervals. In some embodiments, the scheduler 216 generates an adaptive schedule wherein the interval between one comparison and the next is based on one or more external factors. For example, the scheduler 216 may reduce the interval in response to a change in the difference between the adaptive filter response and the baseline response.

The notifier 218, in some embodiments, generates a notification in response to a change in the difference between the adaptive filter response and the baseline response that exceeds a predetermined threshold. For example, a user may experimentally determine a threshold that is below the difference created when a person enters the monitored volume 102, leading to an inference that the acoustic environment of the monitored volume 102 has changed in a way that might indicate that a person has entered. The notifier 218 may generate a notification that is transmitted to a device external to the response analyzer 108, such as by initiating a text message to a predetermined cell phone or by notifying a web service.

In some embodiments, the noise filter 220 modifies the operation of the notifier 218. The noise filter 220 may determine that a change in the difference generated by the DSP 212 is the result of something other than a change in the monitored volume 102 that should lead to notification. For example, a change in temperature or the activation of a heating or cooling system may change the acoustic response of the monitored volume 102 enough to exceed the threshold operated by the notifier 218. In this example, the noise filter 220 may prevent the notifier 218 from issuing a notification. In certain embodiments, the noise filter 220 uses statistics and other information about the data samples to determine whether or not to raise a notification. In some embodiments, the noise filter 220 receives one or more external inputs, such as a temperature input. In one embodiment, the noise filter 220 is programmed to recognize characteristics of a change in differences between input and output signals that are “noise” that should not lead to notification.

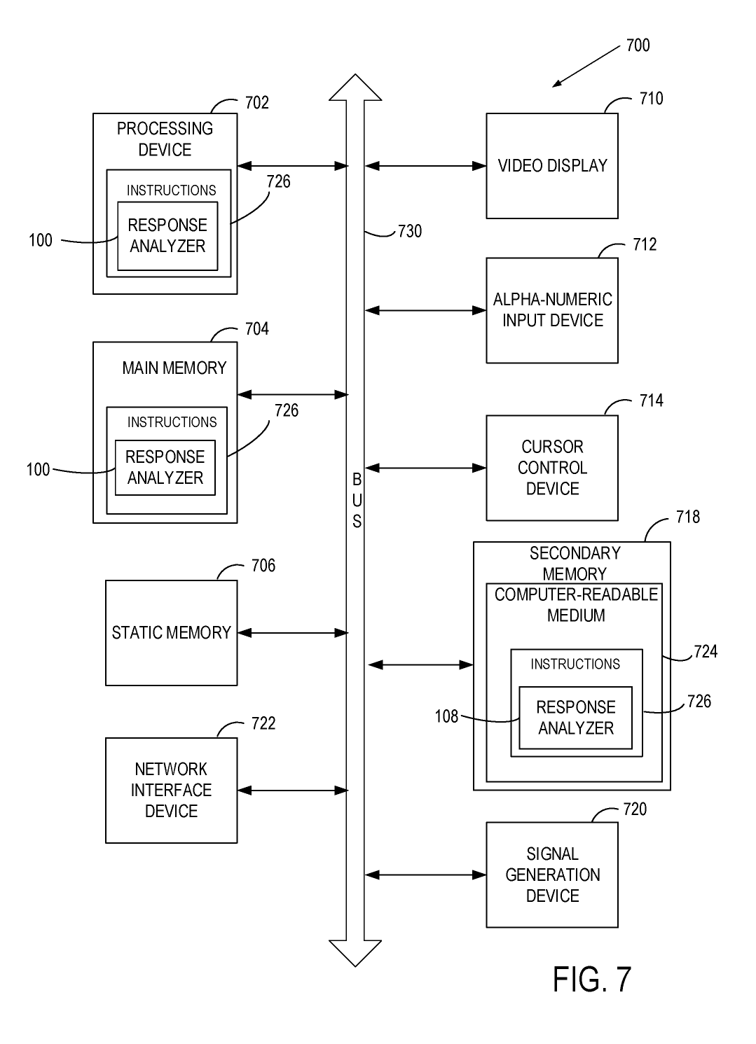

In some embodiments, the response analyzer includes the processor 224. The processor 224 operates one or more of the other elements of the response analyzer 108. For example, the scheduler 216 may operate on the processor 224. The processor 224 may be any type of processor known in the art. Examples of processors 224 are described below in relation to FIG. 7.

The response analyzer 108, in one embodiment, is operated on a single physical device. In an alternative embodiment, the response analyzer 108 operates within a system made up of more than one device. In some embodiments, the devices of the system are separated by a distance and connected via an electrical network. In certain embodiments, the electrical network includes one or more components of a wired network. In some embodiments, the electrical network includes one or more components of a wireless network. For example, a “dumb” machine may have a noise sequence stored in memory. This sequence may be output to a speaker 104 while recording to memory the sound picked up by the microphone 106. The microphone recording may be relayed via a communication network to a “smart” machine that does the processing and determines whether to alarm or not. The “dumb” machine may include memory, a sound interface, and a network interface, but it not be configured to process the excitation signal or the microphone signal. In one embodiment, a remote computer system may be configured to process data generated by and/or collected by the “dumb” machine.

FIG. 3 is a block diagram depicting one embodiment of the DSP 212 of FIG. 2. The DSP 212 includes an excitation signal receiver 302, a microphone signal receiver 304, an adaptive filter generator 306, a baseline selector 308, a comparison module 310, and a difference trigger 312. The DSP 212 processes the excitation signal and the microphone signal to determine a difference between the adaptive filter response and the baseline response.

The excitation signal receiver 302, in some environments, receives the signal generated by the signal generator 202. The microphone signal receiver 304 receives the signal provided from the microphone 106. The adaptive filter generator 306 uses the excitation signal and the microphone signal to generate an adaptive filter to apply to the excitation signal or the microphone signal. The adaptive filter, when applied to the appropriate signal, reduces the difference between the filtered excitation signal and the microphone signal. In one embodiment, the excitation signal as modified by the adaptive filter is the adaptive filter output, and a signal based on the microphone signal is the physical path output. The adaptive filter response corresponds to the physical environment of the monitored volume 102. Changes in the monitored volume 102, such as adding objects to or moving objects within the monitored volume 102, change the response of the monitored volume 102 to pressure waves. This change in response may result in a change to the adaptive filter response.

In one embodiment, the adaptive filter generator 306 uses numerical optimization to generate the adaptive filter. For example, the adaptive filter generator 306 may use a least mean square (“LMS”) method to determine filter coefficients that minimize the difference between the adaptive filter output and the microphone signal. The adaptive filter may be generated using any method known in the art, including, but not limited to, recursive least squares, mutidelay block frequency domain, and subband adaptive filters. The filter generator 306 may use an iterative method to converge toward an optimal filter.

In addition to the adaptive filtering system described herein, any alternative known system identification method may be employed to model the response of the monitored volume 102 and should be considered to be within the scope of this disclosure. For example, in one alternative embodiment, the DSP 212 operates without the use of an adaptive filter generator 306. The excitation signal in this example embodiment may contain information to generate white noise at the speaker 106. The cross-correlation between the excitation signal and the microphone signal may be used to generate an estimate for the impulse response of the monitored volume 102. The cross-correlation may be approximated by a sample average. In some embodiments, the accumulation in the averaging operation is performed at a lower rate than the sample rate. This approach may be advantageous when using a hardware platform that is computationally constrained.

It is possible to estimate the monitored volume response without the use of an adaptive filter. If the excitation (speaker) signal is white noise, then a simplified method may be used. It is well known in the area of system identification that the cross-correlation between the white noise fed to the speaker and the signal returned by the microphone yields an estimate for the impulse response of the monitored volume. This simplified method could be used advantageously when implementing this concept on a computer platform that is computationally constrained. The cross-correlation may be approximated using a sample average. The accumulation in the averaging operation may be performed at a lower rate than the sample rate. This is a somewhat different approach than using adaptive filtering. Adaptive filtering and cross-correlation are two of among many possibilities.

The baseline selector 308, in certain embodiments, selects an adaptive filter response generated by the adaptive filter generator 306 and designates it as a baseline. The baseline may represent an expected response of the monitored volume 102. The baseline may be selected by the baseline selector 308 in response to one or more predetermined characteristics. For example, an adaptive filter may be selected as a baseline in response to a period of time over which several generated adaptive filters are similar. In another example, the baseline may be selected by the baseline selector 308 in response to an input by a user.

The comparison module 310, in one embodiment, compares the adaptive filter response generated by the adaptive filter generator 306 to a baseline selected by the baseline selector 308. The comparison module 310 uses numerical methods to determine a difference between the adaptive filter and the baseline. In response to the difference exceeding a predetermined threshold, the difference trigger 312 indicates a change in the monitored volume 102.

The difference trigger 312 may be configured with a threshold to manage the magnitude of difference required to activate the difference trigger 312. In some embodiments, the threshold may be received from a user. In certain embodiments, the threshold may be calculated experimentally, such as by adding or moving objects in the monitored volume 102 and basing the threshold on the difference between a filter generated before the change in the monitored volume 102 and a filter generated after the change in the monitored volume 102. In some embodiments, the difference trigger 312 provides a signal used by the notifier 218.

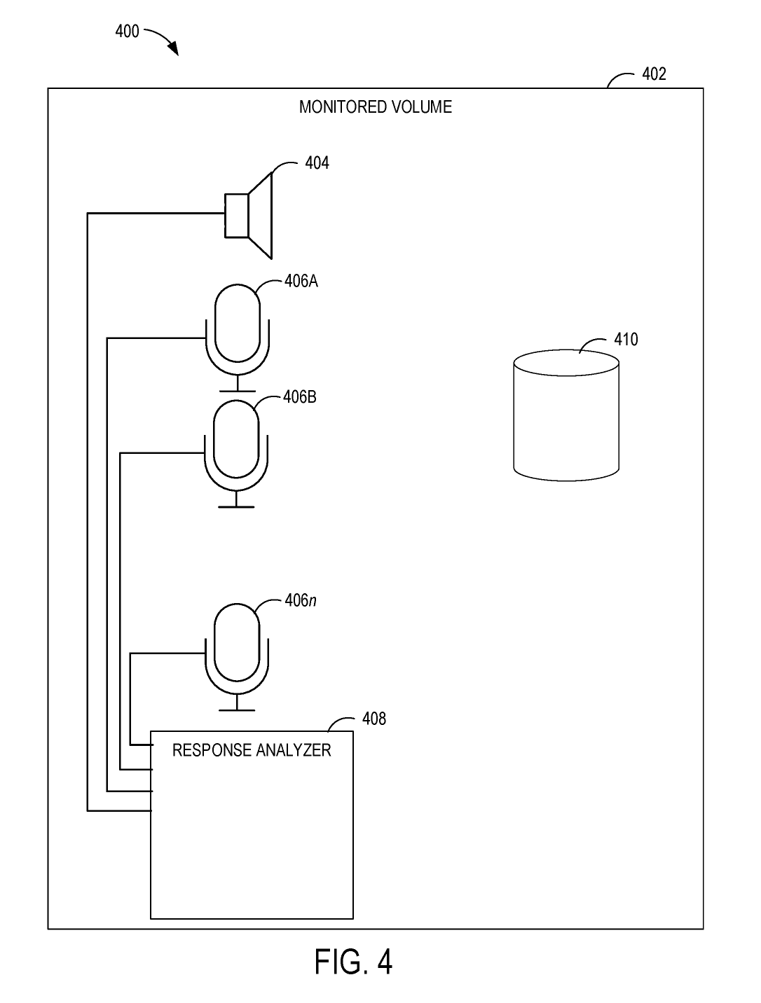

FIG. 4 depicts one embodiment of a system 400 for an acoustic response monitor including a plurality of microphones. The system 400 includes a monitored volume 402, a speaker 404, a plurality of microphones 406A-406n (collectively 406), and a response analyzer 408. The system 400 calculates an acoustic response baseline for the monitored volume 402 and monitors the monitored volume 402 to determine a change to the acoustic response of the monitored volume 402.

The components of the system 400 are similar to like named components described in relation to FIGS. 1-3 above. The system 400 may include any number of microphones 406. In certain embodiments, the response analyzer 408 generates an adaptive filter corresponding to each of the microphones 406. The response analyzer 408 calculates differences for each adaptive filter corresponding to each microphone 406 over time.

In some embodiments, the differences for a given time between the current filter for each microphone 406 and the baseline for each microphone 406 may be averaged to compute a system difference. In one embodiment, the average between differences may be weighted by microphone, such that results from one or more microphones 406 are given more weight than results from one or more other microphones 406.

In certain embodiments, the plurality of microphones 406 are all located at substantially the same location. For example, the microphones 406 may all be mounted within a single enclosure. In another embodiment, one or more of the plurality of microphones 406 are distributed around the monitored volume 402.

The plurality of microphones 404 may produce a more robust measure of change in the monitored volume 402 relative to a single microphone system. In some embodiments, the plurality of microphones 404 may better distinguish movement of an object 410 within the monitored volume 402.

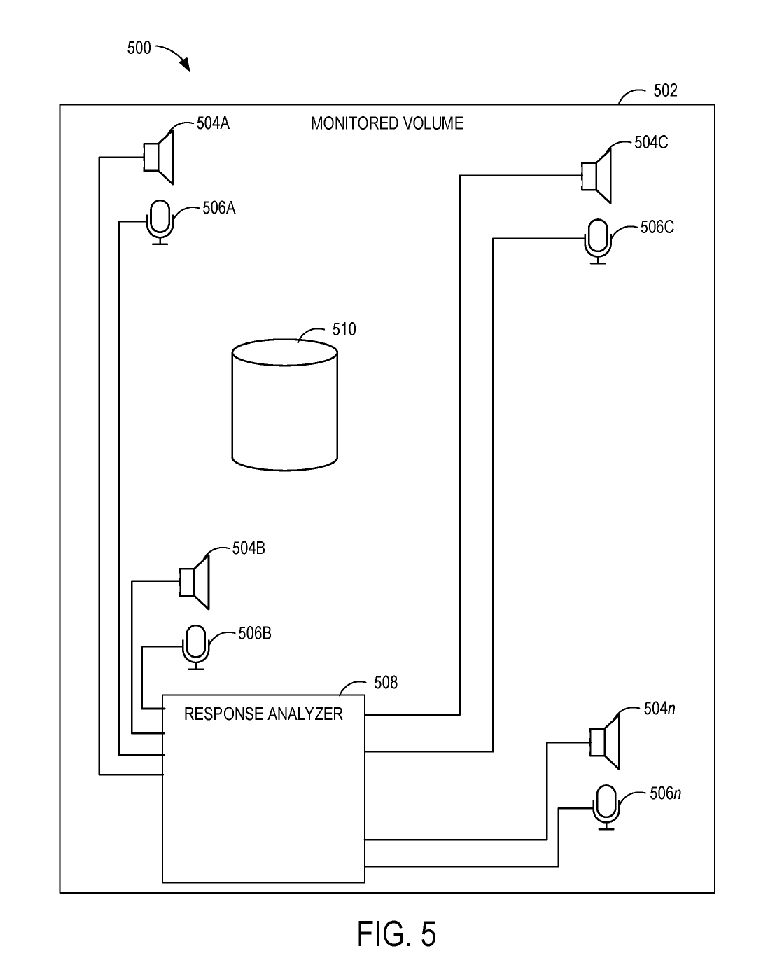

FIG. 5 depicts one embodiment of a system 500 for an acoustic response monitor including a plurality of monitoring areas within a monitored volume 502. The system 500 includes a plurality of speakers 504A-504n (collectively 504), a plurality of microphones 506A-506n (collectively 506), and a response analyzer 508. The system 500 calculates an acoustic response baseline for the monitored volume 502 and monitors the monitored volume 502 to determine a change to the acoustic response of the monitored volume 502.

The components of the system 500 are similar to like named components described above in relation to FIGS. 1-4. The system 500 may include a plurality of pairs of speakers 504 and microphones 506. The pairs may be distributed over a relatively large monitored volume 502. By distributing speakers 504 and microphones 506, the relatively large monitored volume 502 may be monitored by the response analyzer 506.

The response analyzer 508 generates baselines and scheduled adaptive filters for each speaker/microphone pair. In response to changes between the baselines and a generated adaptive filter, the response analyzer 508 indicates a change in the environment of the monitored volume 502.

In one embodiment, the speaker/microphone pairs are distributed far enough apart that they do not substantially interact with one another when the response analyzer 508 generates adaptive filters for each pair. In another embodiment, a particular time is associated with a particular speaker/microphone pair such that the pairs do not interfere with one another. In yet another embodiment, a particular frequency band is associated with a particular speaker/microphone pair. In this embodiment, the response analyzer 508 filters frequencies outside the assigned frequency band for the speaker/microphone pair, thus reducing interference from other speaker/microphone pairs.

In one embodiment, the response analyzer 508 may associate a change in the monitored volume 502 with a particular area within the monitored volume 502. For example, one speaker/microphone pair may indicate a change above a threshold, while other speaker/microphone pairs may not indicate a change above a threshold. In this example, the response analyzer 508 may indicate that the change is likely associated with an area proximal to the speaker/microphone pair that exceeded the threshold.

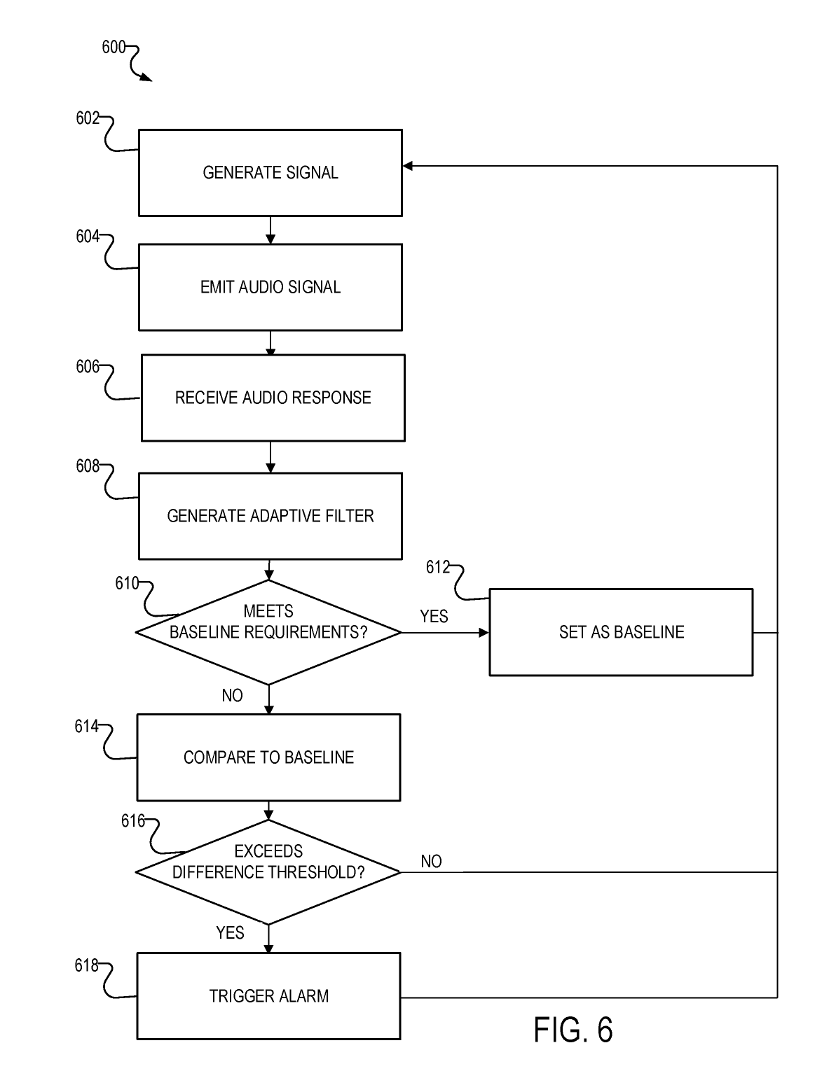

FIG. 6 is a flowchart depicting one embodiment of a method for operating an acoustic response monitor. The method is in certain embodiments a method of use of the system and apparatus of FIGS. 1-5, and will be discussed with reference to those figures. Nevertheless, the method may also be conducted independently thereof and is not intended to be limited specifically to the specific embodiments discussed above with respect to those figures.

FIG. 6 illustrates a method 600 for operating an acoustic response monitor. As shown in FIG. 6, the signal generator 202 generates 602 a signal. The generated signal may correspond to a pressure wave to be created by a speaker 104. The generated signal may correspond to a sound within the average range of human hearing, frequencies above the average range of human hearing, frequencies below the average range of human hearing, or a combination thereof. The generated signal or a signal based on the generated signal is the excitation signal from which the adaptive filter output is generated.

The speaker 104 emits 604 an audio signal based on the generated signal. The audio signal may be music, speech, comfort sounds, white noise, pink noise, an impulse sound, or any other audible sound. In another embodiment, the emitted audio signal may be outside the average range of human hearing.

A microphone 106 receives 606 an audio response including the audio signal emitted by the speaker 104 as modified by traveling within the monitored volume 102. The audio signal reflects and otherwise interacts with surfaces and objects within the monitored volume 102 before being received 606 by the microphone 106. The microphone generates a microphone signal that is the basis of the physical path output. The physical path refers to the response of the monitored volume 102.

The adaptive filter generator 306 generates 608 an adaptive filter based on the excitation signal and the microphone signal. The adaptive filter response corresponds to acoustic response of the monitored volume 502. The adaptive filter, when applied to the excitation signal, is generated 608 to minimize the difference between the filtered excitation signal and the microphone signal.

The baseline selector 308 determines 610 if the generated adaptive filter response meets the requirements of a baseline. If the adaptive filter response meets the requirements of a baseline, the adaptive filter response is set 612 as a baseline. Baseline requirements may include a predetermined number of consecutive similar adaptive filter responses being generated, selection by input from a user, the lack of a current baseline, or other requirements. In response to selection of a baseline, the method returns to generate 602 a signal after a predetermined period of time.

If the adaptive filter response does not meet the requirements of a baseline, it is compared 614 to a baseline by the comparison module 310. The comparison module 310 determines 616 if the difference between the adaptive filter response and the baseline response exceeds a predetermined threshold. If the difference does not exceed the threshold, the response analyzer 108 determines that significant change in the monitored volume 102 has not taken place and the method returns to generate 602 a signal after a predetermined time.

If the difference exceeds the threshold, the difference trigger 312 triggers 618 an alarm. In response, the notifier 218 may notify a user that a significant change has occurred within the monitored volume 102. In response to triggering 618 the alarm, the method returns to generate 602 a signal after a predetermined time.

In one embodiment, the system 100 substantially continuously generates 602 an excitation signal, emits 604 an audio signal based on the excitation signal, receives 606 an audio response, generates 608 an adaptive filter and performs the other steps of the method 600. The system 100 may execute one or more steps of the method 600 at any rate, including, but not limited to, thousands of times per second, once per second, once every 10 seconds, once every minute, once every hour, and once every day.

FIG. 7 is a diagram of one embodiment of a computer system 700 for facilitating the execution of the response analyzer 108. Within the computer system 700 is a set of instructions for causing the machine to perform any one or more of the methodologies discussed herein. In alternative embodiments, the machine may be connected (e.g., networked) to other machines in a LAN, an intranet, an extranet, or the Internet. The machine can be a host in a cloud, a cloud provider system, a cloud controller or any other machine. The machine can operate in the capacity of a server or a client machine in a client-server network environment, or as a peer machine in a peer-to-peer (or distributed) network environment. The machine may be a personal computer (PC), a tablet PC, a console device or set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The exemplary computer system 700 includes a processing device 702, a main memory 704 (e.g., read-only memory (ROM), flash memory, dynamic random access memory (DRAM) such as synchronous DRAM (SDRAM) or DRAM (RDRAM), etc.), a static memory 706 (e.g., flash memory, static random access memory (SRAM), etc.), and a secondary memory 718 (e.g., a data storage device in the form of a drive unit, which may include fixed or removable computer-readable storage medium), which communicate with each other via a bus 730.

Processing device 702 represents one or more general-purpose processing devices such as a microprocessor, central processing unit, or the like. More particularly, the processing device 702 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 702 may also be one or more special-purpose processing devices such as an application specific integrated circuit (ASIC), a field programmable gate array (FPGA), a digital signal processor (DSP), network processor, or the like. Processing device 702 is configured to execute the instructions 726 for performing the operations and steps discussed herein.

The computer system 700 may further include a network interface device 722. The computer system 700 also may include a video display unit 710 (e.g., a liquid crystal display (LCD) or a cathode ray tube (CRT)) connected to the computer system through a graphics port and graphics chipset, an alphanumeric input device 712 (e.g., a keyboard), a cursor control device 78 (e.g., a mouse), and a signal generation device 720 (e.g., a speaker).

The secondary memory 718 may include a machine-readable storage medium (or more specifically a computer-readable storage medium) 724 on which is stored one or more sets of instructions 726 embodying any one or more of the methodologies or functions described herein. In one embodiment, the instructions 726 include instructions for the prescription manager 108. The instructions 726 may also reside, completely or at least partially, within the main memory 704 and/or within the processing device 702 during execution thereof by the computer system 700, the main memory 704 and the processing device 702 also constituting machine-readable storage media.

The computer-readable storage medium 724 may also be used to store the instructions 726 persistently. While the computer-readable storage medium 724 is shown in an exemplary embodiment to be a single medium, the term “computer-readable storage medium” should be taken to include a single medium or multiple media (e.g., a centralized or distributed database, and/or associated caches and servers) that store the one or more sets of instructions. The term “computer-readable storage medium” shall also be taken to include any medium that is capable of storing or encoding a set of instructions for execution by the machine and that cause the machine to perform any one or more of the methodologies of the present invention. The term “computer-readable storage medium” shall accordingly be taken to include, but not be limited to, solid-state memories, and optical and magnetic media.

The instructions 726, components and other features described herein can be implemented as discrete hardware components or integrated in the functionality of hardware components such as ASICS, FPGAs, DSPs or similar devices. In addition, the instructions 726 can be implemented as firmware or functional circuitry within hardware devices. Further, the instructions 726 can be implemented in any combination hardware devices and software components.

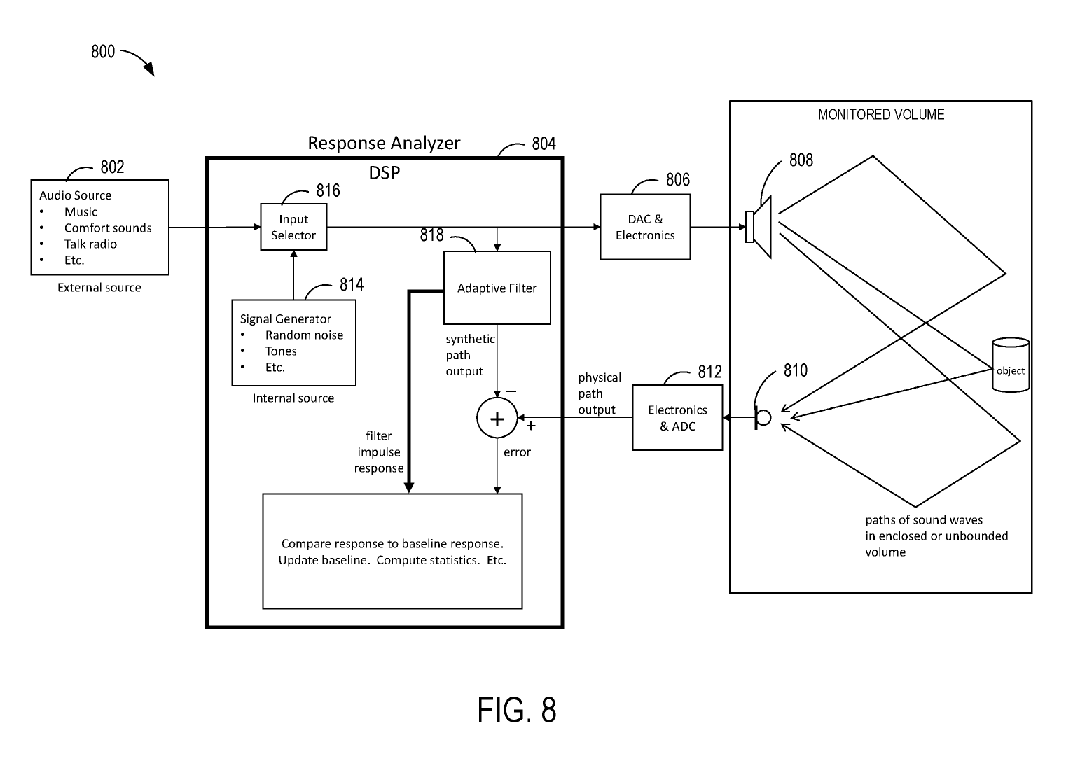

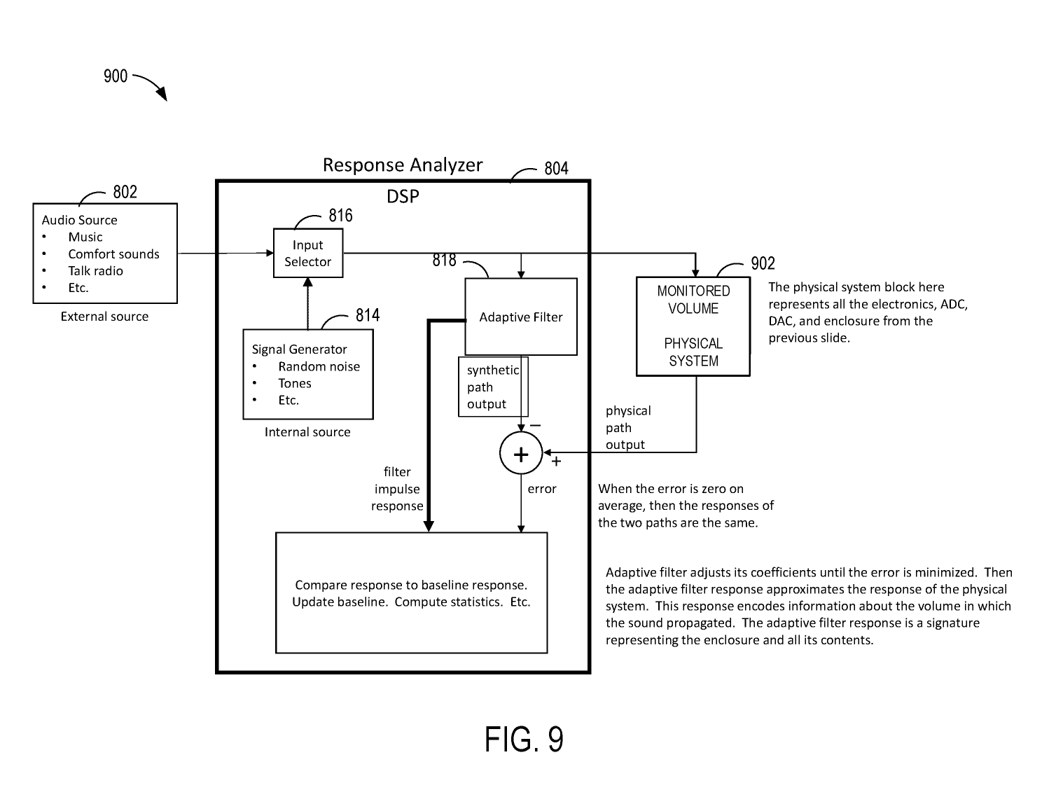

FIGS. 8 and 9 depict one embodiment of a system 800 for a response analyzer. The system 800 includes an external audio source 802, a response analyzer 804, an output stage 806, a speaker, 808, a microphone 810, and an input stage 812. The system analyzes a monitored volume to monitor for a change in acoustic response of the monitored volume.

In one embodiment, the external audio source 802 provides an electrical signal containing audio information. The electrical signal may correspond to any type of audio. For example, the electrical signal may be used to generate music, comfort sounds, talk radio, or any other type of audio. The external audio source 802 may be a streaming audio source configured to deliver audio information over a network, such as the internet. Examples of external streaming audio sources include Spotify®, iTunes®, and a DLNA server.

In an alternative embodiment, an electrical signal containing audio information is provided by in internal signal generator 814. The internal signal generator may be configure to supply a signal containing any type of audio information, including, but not limited to, random noise and tones. In some embodiments, an input selector 816 is configured to allow selection between an external audio source 802 and an internal signal generator 814.

The signal containing audio information provided by the external audio source 802 or the signal generator 814 is referred to herein as the “excitation signal.” The response analyzer 804, in one embodiment, provides the excitation signal or a signal based on the excitation signal to the output stage 806. The output stage may prepare the signal for use by the speaker 808. The output stage may include a DAC, an amplifier, or other electronics.

The speaker 808, in certain embodiments, is a transducer for converting an electrical signal to sound. The speaker 808 may produce sound based on the excitation signal provided by the response analyzer 804.

Sound from the speaker 808 may propagate through a volume of fluid in which the speaker 808 is disposed. For example, the sound may travel within an air-filled room. As the sound travels through the room, it reflects off of and is absorbed by the various objects and boundaries within the room.

In some embodiments, the microphone 810, is a transducer that converts sound to an electrical signal corresponding to the received sound. The microphone 810 may receive the sound generated by the speaker 808 as modified by various objects and boundaries and generate a corresponding electrical signal.

The signal generated by the microphone 812 (the “microphone signal”) is processed by the input stage 812 in certain embodiments. The input stage 812 may include an ADC, an amplifier, or other electronics. The signal as processed by the input stage 812 is transmitted to the response analyzer and represents the physical path output.

Collectively, the output stage 806, the speaker 808, the microphone 810, and the input stage 812 are referred to herein as the “physical system” 902.

An adaptive filter generated by an adaptive filter generator 818 modifies the excitation signal in some embodiments. The filtered excitation signal is the “adaptive filter output.” The response analyzer 804 compares the physical path output to the adaptive filter output. The adaptive filter may be iteratively determined by the adaptive filter generator 818 such that the difference between the physical path output and the adaptive filter output are minimized or reduced below a predetermined threshold.

The response analyzer 804, in certain embodiments, monitors the generated adaptive filter to update a baseline. In some embodiments, the response analyzer 804 triggers an alarm in response to a change in the adaptive filter from a baseline that is greater than a predetermined threshold.

In the above description, numerous details are set forth. It will be apparent, however, to one skilled in the art, that the present invention may be practiced without these specific details. In some instances, well-known structures and devices are shown in block diagram form, rather than in detail, in order to avoid obscuring the present invention.

Some portions of the detailed description are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussion, it is appreciated that throughout the description, discussions utilizing terms such as “providing,” “generating,” “installing,” “monitoring,” “enforcing,” “receiving,” “logging,” “intercepting,” “computing,” “calculating,” “determining,” “presenting,” “processing,” “confirming,” “publishing,” “receiving,” “applying,” “detecting,” “selecting,” “updating,” “assigning,” or the like, refer to the actions and processes of a computer system, or similar electronic computing device, that manipulates and transforms data represented as physical (e.g., electronic) quantities within the computer system's registers and memories into other data similarly represented as physical quantities within the computer system memories or registers or other such information storage, transmission or display devices. In addition, unless specifically stated otherwise as apparent from the following discussion, it is appreciated that throughout the description, discussions utilizing terms such as “manager,” “receiver,” “generator,” “tracker,” “biaser,” “calculator,” “associator,” detector,” “publisher,” or the like, refer to processes operating on a computer system, or similar electronic computing device, that manipulates and transforms data represented as physical (e.g., electronic) quantities within the computer system's registers and memories into other data similarly represented as physical quantities within the computer system memories or registers or other such information storage, transmission or display devices.

It is to be understood that the above description is intended to be illustrative, and not restrictive. Many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. Accordingly, the specification and drawings are to be regarded in an illustrative sense rather than a restrictive sense. The scope of the invention should, therefore, be determined with reference to the appended claims, along with the full scope of equivalents to which such claims are entitled.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

It should also be noted that at least some of the operations for the methods described herein may be implemented using software instructions stored on a computer useable storage medium for execution by a computer. Embodiments of the invention can take the form of an entirely hardware embodiment, an entirely software embodiment, or an embodiment containing both hardware and software elements. In one embodiment, the invention is implemented in software, which includes but is not limited to firmware, resident software, microcode, etc.

Furthermore, embodiments of the invention can take the form of a computer program product accessible from a computer-usable or computer-readable storage medium providing program code for use by or in connection with a computer or any instruction execution system. For the purposes of this description, a computer-usable or computer readable storage medium can be any apparatus that can store the program for use by or in connection with the instruction execution system, apparatus, or device.

The computer-useable or computer-readable storage medium can be an electronic, magnetic, optical, electromagnetic, infrared, or semiconductor system (or apparatus or device), or a propagation medium. Examples of a computer-readable storage medium include a semiconductor or solid state memory, magnetic tape, a removable computer diskette, a random access memory (RAM), a read-only memory (ROM), a rigid magnetic disk, and an optical disk. Current examples of optical disks include a compact disk with read only memory (CD-ROM), a compact disk with read/write (CD-R/W), and a digital video disk (DVD).

An embodiment of a data processing system suitable for storing and/or executing program code includes at least one processor coupled directly or indirectly to memory elements through a system bus such as a data, address, and/or control bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers. Additionally, network adapters also may be coupled to the system to enable the data processing system to become coupled to other data processing systems or remote printers or storage devices through intervening private or public networks. Modems, cable modems, and Ethernet cards are just a few of the currently available types of network adapters.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. An acoustic response monitor comprising:
a speaker configured to generate a sound in response to an excitation signal;
a microphone configured to generate a microphone signal in response to a sound;
a response analyzer in electrical communication with the speaker and the microphone, the response analyzer configured to:
generate an adaptive filter to minimize a difference between the excitation signal as modified by the adaptive filter and the microphone signal;
determine a difference between the adaptive filter and a previously generated adaptive filter;
trigger an alarm if the difference exceeds a predetermined threshold.

2. The acoustic response monitor of claim 1, wherein the adaptive filter is correlated to an acoustic response of a monitored volume.

3. The acoustic response monitor of claim 2, wherein a determination that a characteristic of the monitored volume has changed is correlated to the difference exceeding the predetermined threshold.

4. The acoustic response monitor of claim 2, wherein the monitored volume comprises a gas.

5. The acoustic response monitor of claim 2, wherein the monitored volume comprises a liquid.

6. The acoustic response monitor of claim 2, wherein the monitored volume comprises a solid.

7. The acoustic response monitor of claim 1, wherein the adaptive filter is represented in a format selected from the group consisting of an impulse response, a frequency response, a physical ray-tracing model, and reflection coefficients.

8. The acoustic response monitor of claim 1, wherein the adaptive filter is generated using an algorithm selected from the group consisting of a least mean square algorithm, a recursive least squares algorithm, and an affine projection algorithm.

9. The acoustic response monitor of claim 1, wherein the adaptive filter is applied in a domain selected from the group consisting of a time domain, a frequency domain, and a subband adaptive filter structure.

10. The acoustic response monitor of claim 1, further comprising a noise filter configured to filter external sounds from microphone signal.

11. The acoustic response monitor of claim 10, wherein the noise filter uses double-talk detection.

12. The acoustic response monitor of claim 1, wherein the excitation signal is continuous.

13. The acoustic response monitor of claim 1, wherein the excitation signal is generated at a predetermined interval.

14. The acoustic response monitor of claim 1, wherein the excitation signal is generated in response to a detected event.

15. The acoustic response monitor of claim 1, wherein the excitation signal causes the speaker to generate a sound having characteristics selected from the group consisting of white noise, shaped noise, music, speech, chirps, ultrasound, and infrasound.

16. The acoustic response monitor of claim 1, further comprising a second microphone configured to generate a second microphone signal in response to a sound, wherein the response analyzer is configured to:
generate a second adaptive filter to minimize a difference between the excitation signal as modified by the adaptive filter and the second microphone signal;
determine a second difference between the second adaptive filter and a previously generated second adaptive filter;
trigger an alarm if the second difference exceeds a predetermined threshold.

17. The acoustic response monitor of claim 16, wherein the second microphone is disposed a predetermined distance from the microphone.

18. The acoustic response monitor of claim 1, further comprising a second speaker configured to generate a second sound in response to a second excitation signal, wherein the response analyzer is configured to:
generate a second adaptive filter to minimize a difference between the second excitation signal as modified by the adaptive filter and the microphone signal;
determine a second difference between the second adaptive filter and a previously generated second adaptive filter;
trigger an alarm if the second difference exceeds a predetermined threshold

19. The acoustic response monitor of claim 18, wherein the second speaker is disposed a predetermined distance from the speaker.
